(19) United States
(12) Patent Application Publication
(10) Pub. No.: US 2026/0298986 A1
(43) Pub. Date: Oct. 1, 2026

(54) MEASUREMENT SYSTEM

(71) Applicant: SEIKOH GIKEN Co., Ltd., Matsudo-shi (JP)

(72) Inventor: Ryuji OSAWA, Matsudo-shi (JP)

(21) Appl. No.: 19/560,139

(22) Filed: Mar. 9, 2026

(30) Foreign Application Priority Data
Mar. 28, 2025 (JP) 2025-054730

(51) Int. Cl. G01R 15/22; G01R 15/18; G01R 29/12; G01R 33/032

(52) U.S. Cl. CPC G01R 15/22; G01R 15/18; G01R 29/12; G01R 33/032

(57) ABSTRACT

A measurement system includes: an optical voltage probe configured to modulate an input light with a voltage signal at the measurement point and output a modulated light as an optical measurement signal through an optical fiber; an optical electric field probe configured to modulate an input light by a change in an electric field generated due to the electrical shock and output the modulated light as an optical trigger signal through an input/output optical fiber; a light source configured to supply the input light; a signal O/E converter configured to convert the optical measurement signal into an electrical measurement signal; a trigger O/E converter configured to convert the optical trigger signal into an electrical trigger signal; and a measurement device configured to display a signal waveform of the electrical measurement signal using the electrical trigger signal as a trigger.

### CROSS-REFERENCE TO RELATED APPLICATIONS

This patent specification is based on Japanese patent application, No. 2024-054730 filed on May 16, 2025 in the Japan Patent Office, the entire contents of which are incorporated by reference herein.

### TECHNICAL FIELD

The present invention relates to a measurement system for measuring an electrical signal waveform at a measurement point using an optical measurement probe configured to modulate an input light with an electrical signal and output the modulated light as an optical measurement signal through an optical fiber.

### BACKGROUND OF THE INVENTION

In recent years, various control devices using high-speed CPU and the like have been developed. To prevent malfunctions, ESD (Electrostatic Discharge) test including CDM (Charged Device Model) test, noise immunity test and the like are performed on an electrical circuit or an electrical component by charging the electrical circuit or the electrical component and then discharging to ground. In the above described tests, verification is performed according to criteria for determining whether malfunction or destruction occurs when various electrical shocks are applied to the electrical circuit or the electrical component. In this case, it is necessary to accurately measure the input/output signals of the electrical component installed on the electrical circuit board during the test and the waveforms of the electrical signals transmitted through a wiring in order to investigate the cause of failure and improve immunity.

A general method for measuring the electrical signal waveform of the electrical component and the wiring is a method of guiding the electrical signal at the measurement point to a measurement device such as an oscilloscope using an electrical probe having a contact terminal and measuring the transmitted voltage waveform and the like. However, when the ground level of the measurement point differs from that of the measurement device or when measuring a voltage signal between two points that are not grounded, it is difficult to measure the voltage waveform accurately due to the signal interference from the ground, the influence of the capacitance of the electrical probe and the like. Particularly in the high frequency range, the influence of the above-mentioned ground and capacitance is significant. Furthermore, an input impedance and an output impedance are not 50Ω in many integrated circuits such as IC and LSI. Therefore, when the noise voltage is measured by using the electrical probe having a low input impedance, current flows to the electrical probe side and the electrical signals and the noise voltage to be measured are lowered. Furthermore, due to the strong electromagnetic field generated by the electrical shock, the unwanted voltage received by the electrical probe becomes very large. Thus, the electrical signal including the noise voltage that should originally be measured becomes unclear.

As for the means for solving the above described problem, a measurement system using an optical voltage probe that converts a voltage signal into an optical signal and guides the optical signal to a measurement device through an optical fiber has been developed. In the above described method, since the capacitance component of the probe is very small and the input impedance is very high. the original electrical signal and noise voltage are converted into the optical signal without deterioration. Furthermore, since the signal is transmitted as the optical signal through the optical fiber, the measurement point and the measurement device are completely electrically isolated. The optical voltage probe can measure up to high frequency components and can prevent the influence of the ground and the interference of the electrical signal noise during transmission.

Examples of the above described conventional measurement system is described in Patent documents 1 and 2.

Patent document 1 describes the optical voltage probe having a waveguide type optical modulator. This obtains an optical intensity modulation signal by applying the voltage signal of the contact terminals between two modulation electrodes of a branch interference type optical modulator formed on a lithium niobate crystal substrate. A device having a light source and an O/E converter is connected with the optical voltage probe through the optical fiber. Patent document 2 describes the configuration where a package of the optical voltage probe is covered with conductive materials such as a metal or radio wave absorbing materials such as a ferrite.

### PRIOR ART DOCUMENT

### Patent Documents

[Patent document 1] Japanese Unexamined Patent Application Publication No. H8-35998

[Patent document 2] Japanese Unexamined Patent Application Publication No. 2021-165666

### SUMMARY OF THE INVENTION

As described above, the conventional optical voltage probe can eliminate the influence of the ground and can prevent the interference of the electrical signal noise from the wiring leading to the measurement device. Furthermore, in the optical voltage probe of Patent Document 2, the influence of the electromagnetic noise induced in the modulation electrode can be eliminated by covering the package with metal or radio wave absorbing material using the wiring inside the package as an antenna. Thus, more accurate electrical signal waveform can be measured in Patent Document 2 than the conventional electrical probe.

When the signal waveform is measured in the test such as ESD test, it is most important to know the signal waveform at the moment of applying the electrical shock and immediately after that. Conventionally, a trigger signal is inputted to the trigger input terminal of the measurement device such as an oscilloscope that displays the signal waveform by detecting a signal from a device that applies the electrical shock or the electromagnetic wave generated at that time with an antenna. On the other hand, the signal from the optical voltage probe is transmitted through the optical fiber and input to the measurement device after O/E conversion. Generally, since the signal delay time of the optical fiber is considerably larger than that of an electrical cable, the signal from the optical voltage probe reaches the measurement device with a delay of 200 ns or more compared to the trigger signal.

In the measurement device such as an oscilloscope, there is a deskew function that corrects time errors of the measurement system. Thus, it is possible to correct and display a certain degree of delay time. However, when using the optical voltage probe, the delay time difference is large, and since the signal speed is high and display of the signal waveform in a very short time domain (e.g., in a domain of about 0.1 ns) is required, the above described deskew function cannot cope with this. In many cases, the signal waveform with necessary resolution cannot be obtained regarding the moment of applying the electrical shock and immediately after that.

An object of the present invention is to solve the above described problem and to provide a measurement system capable of measuring the signal waveform at the moment of applying the electrical shock and immediately after that when measuring the electrical signal waveform at the measurement point using the optical measurement probe.

For solving the above described problem, the first viewpoint of the measurement system of the present invention is a measurement system for measuring an electrical signal waveform at a measurement point in an electric circuit or an electric component when an electrical shock is applied to the electric circuit or the electric component, the measurement system including: an optical measurement probe configured to modulate a first input light with a voltage signal or a current signal at the measurement point and output a first modulated light as an optical measurement signal through a first optical fiber; an optical trigger probe configured to modulate a second input light by a change in an electric field or a magnetic field generated in a surrounding of the optical trigger probe due to the electrical shock and output a second modulated light as an optical trigger signal through a second optical fiber; a light source configured to supply the first input light and the second input light to the optical measurement probe and the optical trigger probe; a signal O/E converter configured to convert the optical measurement signal into an electrical measurement signal; a trigger O/E converter configured to convert the optical trigger signal into an electrical trigger signal; and a measurement device configured to receive the electrical measurement signal and the electrical trigger signal and display a signal waveform of the electrical measurement signal using the electrical trigger signal as a trigger.

In the conventional measurement system using the optical voltage probe, as described above, due to the delay of the optical measurement signal by the optical fiber, a large arrival time difference between the trigger signal and the signal input to the measurement device occurs, and in many cases, the necessary signal waveform cannot be obtained regarding the moment of applying the electrical shock and immediately after that. In the present invention, a change in the electric field or the magnetic field generated in the surrounding due to the electrical shock is detected using the optical trigger probe that outputs the optical trigger signal as an optical trigger signal through the optical fiber. Similar to the optical measurement signal, the electrical trigger signal transmitted through the optical fiber and obtained by O/E conversion is input to the measurement device. Thus, the trigger signal can be supplied to the measurement device at a time close to the arrival time of the measurement signal. This enables the measurement of the signal waveform at the moment of applying the electrical shock and immediately after that.

Here, the optical measurement probe preferably has a configuration that does not require a power source. It is sufficient that the optical measurement probe modulates the input light with a voltage signal or a current signal at the measurement point and the modulated light is outputted as the optical measurement signal through the optical fiber. For example, an optical voltage probe that converts the voltage signal at the measurement point into an optical intensity modulation signal by an optical modulator and outputs the optical intensity modulation signal, or an optical current probe that detects a magnetic field generated by the current at the measurement point with a magnetic field antenna, converts the magnetic field into a voltage and converts the voltage into an optical intensity modulation signal by an optical modulator and outputs the optical intensity modulation signal, can be used.

Similarly, the optical trigger probe preferably has a configuration that does not require a power source. It is sufficient that the optical trigger probe modulates the input light by a change in the electric field or the magnetic field generated in the surrounding of the optical trigger probe due to the electrical shock and outputs the modulated light as an optical trigger signal through the optical fiber. For example, the optical electric field probe that converts a change in the electric field generated by the electrical shock into an optical intensity modulated light by the optical modulator and outputs the optical intensity modulated light, or an optical magnetic field probe that converts a change in the magnetic field generated by the electrical shock into a voltage with a magnetic field antenna and converts the voltage into an optical intensity modulation signal by an optical modulator and outputs the optical intensity modulation signal, can be used.

Note that the measurement system of the present invention can be effectively used for measuring the signal waveform at the measurement point in various test environment such as various immunity tests where the electrical shock is applied to the electrical circuit or the electrical component, not only in the case of ESD test.

In the second viewpoint of the present invention, the measurement system of the first viewpoint is characterized in that the optical measurement probe is an optical voltage probe configured to measure the voltage signal at the measurement point, and the optical voltage probe includes: an optical modulator configured to convert the voltage signal between two electrode pads into an optical intensity modulation signal and output the optical intensity modulation signal through the first optical fiber; two contact terminals capable of contacting the measurement point; and an electrical line connecting the two contact terminals with the two electrode pads. The invention of this aspect uses a conventional optical voltage probe as the optical measurement probe.

In the third viewpoint of the present invention, the measurement system of the first viewpoint is characterized in that the optical measurement probe is an optical current probe configured to measure the current signal at the measurement point, and the optical current probe includes: an optical modulator configured to convert the voltage signal between two electrode pads into an optical intensity modulation signal and output the optical intensity modulation signal through the first optical fiber; a magnetic field antenna configured to detect a magnetic field generated by a current at the measurement point and convert the magnetic field into a voltage; and an electrical line connecting the magnetic field antenna with the two electrode pads. As the above described magnetic field antenna, a small loop antenna or the like installed in proximity to the measurement point can be used. The power waveforms can also be measured by measuring both the voltage signal and the current signal.

In the fourth viewpoint of the present invention, the measurement system of the first viewpoint is characterized in that the optical trigger probe is an optical electric field probe configured to detect the change in the electric field generated by the electrical shock, the optical electric field probe includes an optical modulator which includes a modulation electrode and is configured to convert the voltage signal induced in the modulation electrode into an optical intensity modulation signal and output the optical intensity modulation signal through the second optical fiber, and the voltage signal is induced in the modulation electrode by the change in the electric field or an antenna configured to induce the voltage by the change in the electric field is connected to the modulation electrode.

In the invention of this aspect, the optical electric field probe using the optical modulator configured to convert the change in the electric field into the optical intensity modulation signal and output the optical intensity modulation signal is used as the optical trigger probe. In this case, the optical modulator having the modulation electrode having a function as an antenna that induces a voltage by the electric field on the spot may be used, or an antenna formed using the same material and process as the modulation electrode on the chip on which the optical modulator is formed may be provided and connected to the modulation electrode.

In the fifth viewpoint of the present invention, the measurement system of the first viewpoint is characterized in that the optical trigger probe is an optical magnetic field probe configured to detect the change in the magnetic field generated by the electrical shock, and the optical magnetic field probe includes: an optical modulator configured to convert the voltage signal between two electrode pads into an optical intensity modulation signal and output the optical intensity modulation signal through the second optical fiber; a magnetic field antenna configured to detect the change in the magnetic field and convert the change into a voltage; and an electrical line connecting the magnetic field antenna with the two electrode pads. As the above magnetic field antenna, a small loop antenna or the like can be used.

In the sixth viewpoint of the present invention, the measurement system of the first viewpoint is characterized in that a plurality of optical measurement probes are provided, and a plurality of electrical measurement signals obtained from the plurality of optical measurement probes is input to the measurement device and the signal waveform of the plurality of electrical measurement signals is simultaneously displayed. In the electrical circuit and the electrical component, it is desired to simultaneously observe the signal waveform at two or more measurement points that output mutually related signals in any cases. The invention of this aspect enables such simultaneous measurement of the signal waveform by using a plurality of optical measurement probes.

In the seventh viewpoint of the present invention, the measurement system of any one of the first to sixth viewpoints is characterized in that a variable optical delay device configured to adjust a delay time of the optical measurement signal or the optical trigger signal is inserted in at least one of between the first optical fiber connected to the optical measurement probe and the signal O/E converter or between the second optical fiber connected to the optical trigger probe and the trigger O/E converter. In the present invention, since the trigger signal and the measurement signal are both transmitted from the test site through the optical fibers, the delay time difference can be made smaller compared to the case where only one uses the electrical cable. However, in order to further reduce the delay time difference, it is necessary to make the lengths of the optical fibers used for the transmission of the trigger signal and the measurement signal equal. This is possible to some extent by selecting the lengths of the optical fibers to be used. However, when the waveforms at shorter time intervals are required, the adjustment becomes easier by inserting a variable optical delay device as in the invention of this aspect. As the variable optical delay device, commercially available devices of various methods such as a method of folding between input and output ports with a prism and making the distance variable, or a method of making the distance passing through a high refractive index medium variable can be used. The invention of this aspect is also effective when simultaneously observing the signal waveforms at a plurality of measurement points without delay time difference. Note that the variable optical delay device may be inserted in either one of the optical fiber transmission path for the optical measurement signal and the optical fiber transmission path for the optical trigger signal, or may be inserted in both transmission paths.

In the eighth viewpoint of the present invention, the measurement system of the seventh viewpoint is characterized in that the electrical shock is applied by an ESD (Electrostatic Discharge) test or a CDM (Charged Device Model) test on the electrical circuit or the electrical component.

As the optical modulator used in the optical measurement probe and the optical trigger probe of the present invention, a branch interference type optical modulator using an optical waveguide formed on a conventionally used lithium niobate crystal can be used. The basic configuration of the branch interference type optical modulator comprises an input optical waveguide extending from the light incidence side, two phase shift waveguides extending from the input optical waveguide and branched into two, an output optical waveguide where the two phase shift optical waveguides merge and lead to the light emission side, and modulation electrodes arranged parallel to the phase shift waveguides. A voltage signal is applied to the phase shift waveguide through the modulation electrode, the refractive index of the phase shift optical waveguide is changed, and the light that has passed through the two phase shift optical waveguides merges and interferes. Thus, the light intensity is modulated. Since a small, highly efficient and broadband optical modulator can be obtained, it is suitable for application to the present invention.

In this case, as the modulation electrode, a so-called split electrode comprising a plurality of electrodes that are divided in the longitudinal direction and capacitively coupled to each other can be used. An effective means of improving the trade-off relationship between the length and the electrical capacitance of the modulation electrode, which is related to the modulation efficiency and the modulation bandwidth, is a split electrode in which one modulation electrode is divided into a plurality of capacitively coupled electrodes. By using the split electrode, a highly efficient and broadband optical modulator can be obtained.

Furthermore, as the optical modulator used in the present invention, a reflection-type optical modulator that reflects and folds back incident light internally may be used, and the input optical fiber and the output optical fiber may be configured as a single input/output optical fiber. The reflection-type optical modulator has a configuration in which the incident light is reflected in the phase shift waveguide and returned to the optical waveguide on the incidence side. By using such a configuration of the reflection-type optical modulator, the light passes through twice the length for the same electrode length compared to a transmission-type optical modulator. Thus, high efficiency and broadband operation of the optical modulator are possible, and miniaturization is also possible. Furthermore, since only one optical fiber is connected to the optical modulator, handling becomes easier.

As described above, according to the present invention, when measuring the electrical signal waveform at the measurement point using the optical measurement probe, a measurement system capable of measuring the signal waveform at the moment of applying the electrical shock and immediately after that can be obtained.

### BRIEF DESCRIPTION OF DRAWINGS

FIG. 1 is a block diagram showing the configuration of a measurement system of the first embodiment.

FIGS. 2A and 2B are configuration diagrams schematically showing an example of the configuration of an optical voltage probe used in the first embodiment. FIG. 2A is a plan view of a transmission type. FIG. 2B is a side view of the transmission type.

FIGS. 3A and 3B are diagrams schematically showing an example of the configuration of a reflection-type optical modulator built into the optical voltage probe used in the first embodiment. FIG. 3A is a plan view. FIG. 3B is a cross-sectional view taken along line A-A.

FIG. 4A is a plan view of a transmission type schematically showing an example of the configuration of an optical electric field probe used in the first embodiment. FIG. 4B is a plan view schematically showing an example of an optical modulator used in the optical electric field probe.

FIG. 5 is a plan view schematically showing another example of an optical modulator used in the optical electric field probe.

FIG. 6 is a block diagram showing the configuration of a measurement system of the second embodiment.

FIG. 7 is a plan view of a transmission type schematically showing an example of the configuration of an optical magnetic field probe used in the second embodiment.

FIG. 8 is a block diagram showing the configuration of a measurement system of the third embodiment.

### DETAILED DESCRIPTION OF THE INVENTION

Hereinafter, the measurement system of the present invention will be explained in detail using the embodiments with reference to the drawings. Note that the same reference numerals are added to the same elements in the explanation of the drawings and the repeated explanation will be omitted.

### First Embodiment

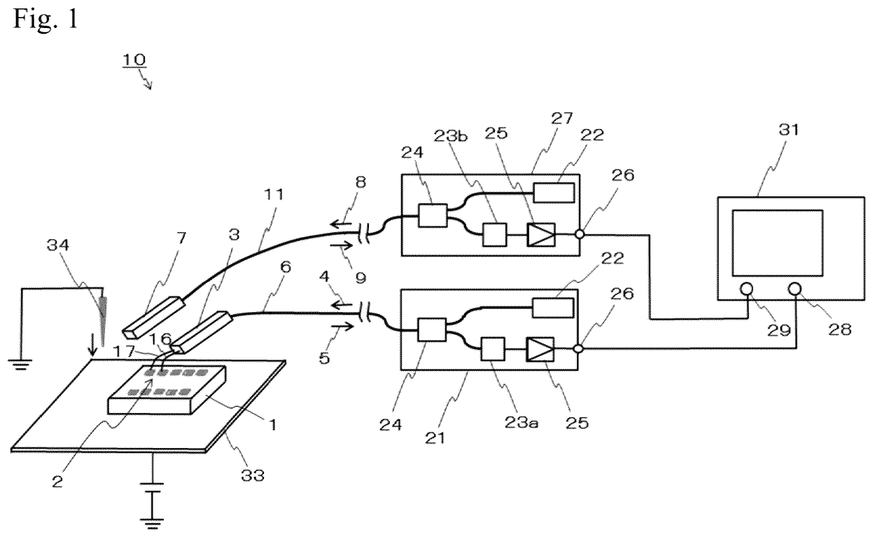

FIG. 1 is a block diagram showing the configuration of a measurement system of the first embodiment. In FIG. 1, a measurement system 10 of the present embodiment is a measurement system for measuring an electrical signal waveform at a measurement point in an electrical component 1 when an electrical shock is applied to the electrical component 1 such as an IC by a CDM test. The measurement system includes: an optical voltage probe 3 configured to modulate an input light 4 with a voltage signal at the measurement point 2 and output the modulated light as an optical measurement signal 5 through an input/output optical fiber 6; and an optical electric field probe 7 configured to modulate an input light 8 by a change in the electric field generated in a surrounding of the optical electric field probe 7 due to the electrical shock and output the modulated light as an optical trigger signal 9 through an input/output optical fiber 11. The measurement system also includes an optical transmission/reception unit for the optical voltage probe 3 and an optical transmission/reception unit for the optical electric field probe 7. The optical transceiver unit 21 includes: a light source 22 such as a semiconductor laser that supplies input light to the optical voltage probe 3; a signal O/E converter 23a; a transmission/reception separator 24 for separating the input light 4 and the optical measurement signal 5; and an amplifier 25. Similarly, the optical transceiver unit 27 includes: a light source 22 that supplies the input light to the optical electric field probe 7; a trigger O/E converter 23b; a transmission/reception separator 24 for separating the input light 8 and the optical trigger signal 9; and an amplifier 25. The light emitted from the light source 22 is coupled to the input/output optical fiber 6 or 11 through the transmission/reception separator 24, and the optical measurement signal 5 or the optical trigger signal 9 returning from the input/output optical fiber 6 or 11 is input to the signal O/E converter 23a or the trigger O/E converter 23b through the transceiver separator 24 respectively, converted into an electrical signal, amplified by the amplifier 25, and output to an output terminal 26. Note that the transmission/reception separator 24 can be configured using any one of an optical circulator, an optical fiber splitter and a semi-transmissive mirror.

The optical voltage probe 3 includes two contact terminals 16 and 17 capable of contacting the measurement point 2. The optical voltage probe 3 is configured to convert a voltage signal between the two contact terminals into an optical intensity modulation signal and output the optical intensity modulation signal as an optical measurement signal 5 through the input/output optical fiber 6. The electrical measurement signal converted from the optical measurement signal 5 is input to a signal input terminal 28 of a measurement device 31 such as an oscilloscope, and the electrical trigger signal converted from the optical trigger signal 9 is input to a trigger input terminal 29 of the measurement device 31. Thus, a signal waveform of the voltage signal at the measurement point 2 is displayed.

The CDM test is a test for inspecting malfunction or destruction of the electrical component 1 that occurs when a voltage is applied to a charging plate 33 to charge the charging plate 33, and a ground pin 34 is brought into contact with the charging plate 33 to discharge the charging plate 33. In the above described CDM test, a high voltage of several kV is generated on the charging plate 33, a current of several A flows during discharge, and an electromagnetic wave of large amplitude is generated near the measurement point by the electrical shock at that time. In the present embodiment, the optical electric field probe 7 is used to detect the change in the electric field generated at the time of the shock and use it as a trigger signal for the measurement device 31.

In the present embodiment, a change in the electric field generated in the surrounding due to the electrical shock is detected using the optical electric field probe that outputs the change as an optical trigger signal through the optical fiber and the optical trigger signal is transmitted through the optical fiber similar to the optical measurement signal. Thus, the electrical trigger signal obtained by O/E conversion is input to the measurement device so that the electrical trigger signal can be supplied to the measurement device at a time close to the arrival time of the electrical measurement signal. As a result of the measurement by the measurement system of the present embodiment, it was confirmed that the signal waveform at the moment of applying the electrical shock and immediately after that can be measured. As described above, by measuring the accurate voltage signal waveform between the terminals of the measurement point 2, the operation at the time of the shock can be grasped, and data for investigating malfunctions and causes of failure can be obtained.

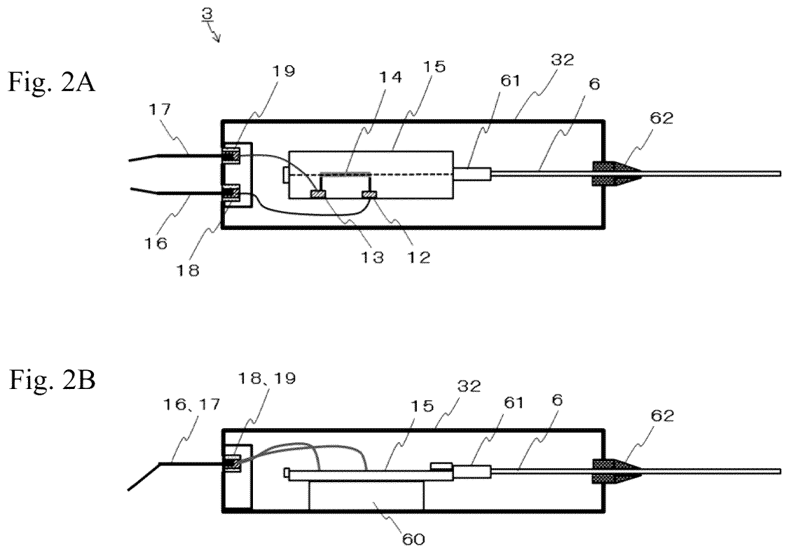

FIGS. 2A and 2B are configuration diagrams schematically showing an example of the configuration of an optical voltage probe used in the present embodiment. FIG. 2A is a plan view of a transmission type. FIG. 2B is a side view of the transmission type. In FIGS. 2A and 2B, the optical voltage probe 3 includes: an optical modulator 15 which includes a modulation electrode 14 having two electrode pads 12 and 13, modulates the intensity of the incident light in accordance with the voltage between the electrode pads 12 and 13 and outputs the modulated light; and an input/output optical fiber 6 connected to the optical modulator 15. The contact terminals 16 and 17 are connected to terminal attachment portions 18 and 19 respectively. The terminal attachment portion 18 is connected to the electrode pad 12, and the terminal attachment portion 19 is connected to the electrode pad 13. The optical modulator 15 is a reflection-type optical modulator that reflects and folds back the incident light internally. The tip of the input/output optical fiber 6 is inserted and fixed in a ferrule 61 in order to adhesively fix the end faces together with the input/output end face of the optical modulator 15.

The optical modulator 15 and a part of the input/output optical fiber 6 are housed in a package 32. The contact terminals 16 and 17 are configured to be detachably attached by contacting the metal tubular portions of the terminal attachment portions 18 and 19 fixed to the package 32 respectively. The metal tubular portion is fixed inside a tubular insulator, and the insulator is fixed to the package 32. The package 32 has a rectangular parallelepiped shape and is made of a metal plate such as aluminum in order to shield external electric fields. The optical modulator 15 is fixed to a base 60 fixed to the package 32, and the input/output optical fiber 6 is fixed to the package 32 by a rubber-like fixing member 62.

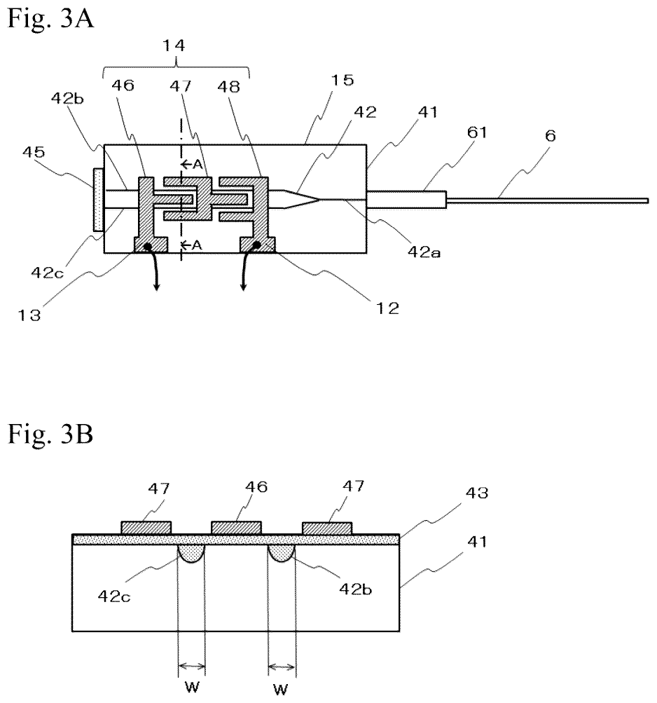

FIGS. 3A and 3B are diagrams schematically showing an example of the configuration of a reflection-type optical modulator 15 built into the optical voltage probe 3 used in the present embodiment. FIG. 3A is a plan view. FIG. 3B is a cross-sectional view taken along line A-A. In FIGS. 3A and 3B, the optical modulator 15 includes: a substrate 41 made by cutting a lithium niobate (LiNbO3) crystal, which is a crystal having an electro-optical effect, in an X-cut orientation; a branch interference type optical waveguide 42 formed on the upper surface side of the substrate 41 by Ti diffusion; a buffer layer 43 arranged on the upper surface side of the substrate 41; a modulation electrode 14 formed of a metal film on the buffer layer 43; and a light reflecting portion 45 installed at one end portion of the substrate 41.

The branch interference type optical waveguide 42 comprises one input/output optical waveguide 42a extending toward the incidence side of the input light, and two phase shift optical waveguides 42b and 42c extending from the input/output optical waveguide 42a and branched into two. In the input/output optical waveguide 42a and the phase shift optical waveguides 42b and 42c, the width W in the direction perpendicular to the extending direction is in the range of 5 to 12 μm and is equal to each other. In addition, the lengths in the extending direction of the phase shift optical waveguides are in the range of 10 to 30 mm and are substantially equal to each other. The phase shift optical waveguides 42b, 42c are separated from each other and extended in parallel to each other so that the center parts of them are separated by a predetermined distance within the range of 15 to 50 μm. The buffer layer 43 is provided for the purpose of preventing a part of the light propagating through the optical waveguide 42 from being absorbed by the modulation electrode 14.

In the optical modulator 15, the modulation electrode 14 is composed of the electrode pads 12 and 13 and a split electrode formed by three electrodes 46, 47, 48 that are divided from each other in a longitudinal direction of the branch interference type optical waveguide 42 and capacitively coupled with each other. Between the electrode pads 12 and 13, the electrodes 46 and 47 and the electrodes 47 and 48 are capacitively coupled with each other and arranged in series. The input/output terminal of the input/output optical fiber 6 is coupled with the light input/output end of the input/output optical waveguide 42a. The light reflecting portion 45 reflects the light incident from the input/output optical waveguide 42a and propagated through the phase shift optical waveguides 42b, 42c to return the light and make the light propagate from the phase shift optical waveguides 42b, 42c to the input/output optical waveguide 42a. When the voltage is applied between the electrode pads 12 and 13, the refractive index change occurs in the phase shift optical waveguides 42b and 42c in an opposite direction to each other. Thus, the phase shift having polarity opposite to each other is made in the light passing through the phase shift optical waveguides 42b and 42c. The intensity change occurs when the lights are joined since the lights are interfered with each other. Consequently, the optical intensity modulation signal having the light intensity change in accordance with the voltage applied between the electrode pads 12 and 13 is obtained.

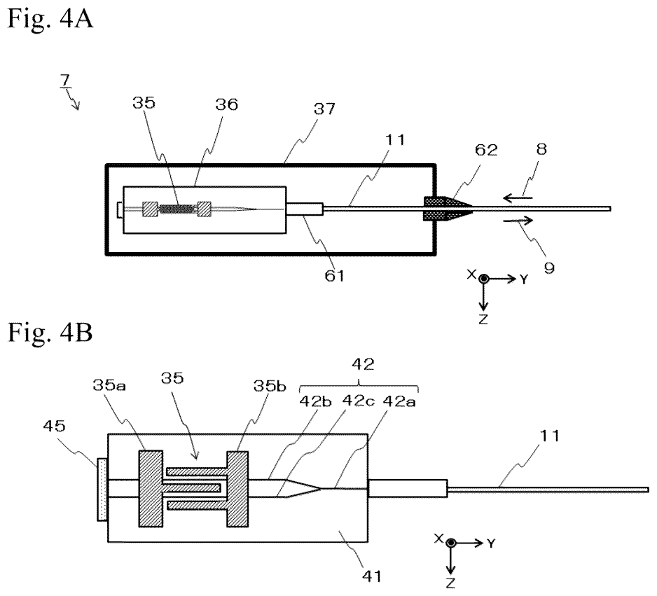

FIG. 4A is a plan view of a transmission type schematically showing an example of the configuration of the optical electric field probe used in the present embodiment. FIG. 4B is a plan view schematically showing an example of the optical modulator used in the optical electric field probe. The optical electric field probe 7 includes an optical modulator 36 having a modulation electrode 35. The optical electric field probe 7 is configured such that a voltage signal is induced in the modulation electrode 35 by a change in the electric field at that position. As shown in FIG. 4B, the optical modulator 36 is a reflection-type optical modulator having a configuration similar to the optical modulator 15 of the optical voltage probe 3. The electrode pads 35a and 35b at both ends of the modulation electrode 35 function as antennas, and the input light 8 input through the input/output optical fiber 11 is converted into an optical intensity modulation signal by the voltage signal induced between the electrode pads 35a and 35b and the optical intensity modulation signal is outputted as the optical trigger signal 9 to the input/output optical fiber 11. The optical electric field probe 7 detects an electric field component in the Y-axis direction. The optical modulator 36 and a part of the input/output optical fiber 11 are housed in a package 37 made of a material such as glass or ceramic that does not block the electric field.

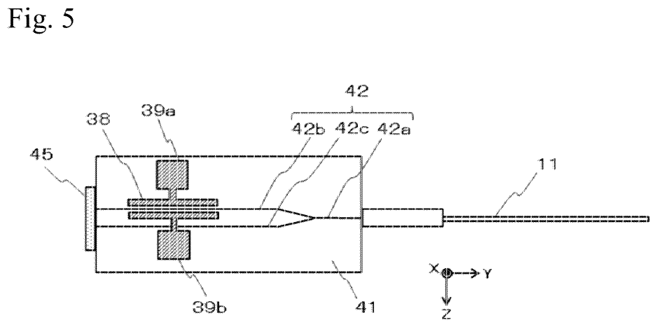

FIG. 5 is a plan view schematically showing another example of the optical modulator used in the optical electric field probe. Antenna pads 39a and 39b are connected to a modulation electrode 38, and a voltage induced in the antenna pads 39a and 39b is applied to the modulation electrode 38 to modulate the input light. The electric field probe using the above described optical modulator detects an electric field in the Z-axis direction.

### Second Embodiment

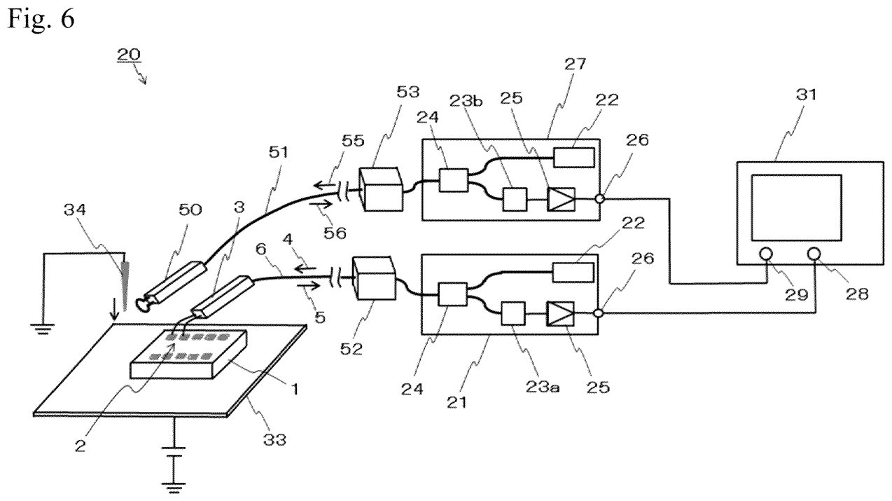

FIG. 6 is a block diagram showing the configuration of a measurement system of the second embodiment. In FIG. 6, the measurement system 20 of the present embodiment is the same as the measurement system 10 of the first embodiment in that an electrical signal waveform is measured at the measurement point 2 when an electrical shock is applied to the electrical component 1 by a CDM test and the optical voltage probe 3, the optical transceiver units 21 and 27 and the measurement device 31 are used. However, the present embodiment differs in that the optical trigger probe is an optical magnetic field probe 50 that detects a change in the magnetic field generated by the electrical shock, and that variable optical delay devices 52 and 53 for adjusting the delay time of the optical measurement signal or the optical trigger signal are inserted between the input/output optical fiber 6 connected to the optical voltage probe 3 and the signal O/E converter 23a and between the input/output optical fiber 51 connected to the optical magnetic field probe 50 and the trigger O/E converter 23b respectively.

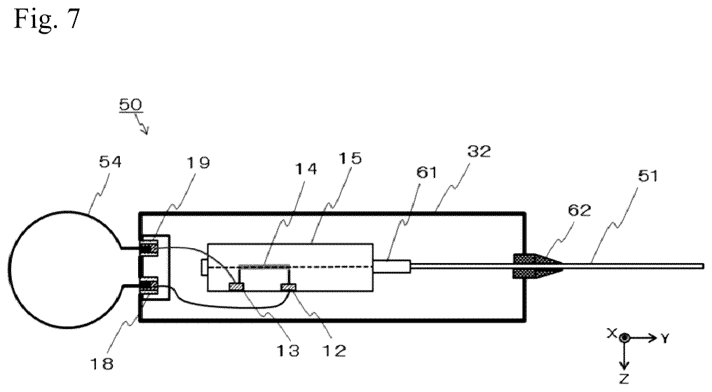

FIG. 7 is a plan view of a transmission type schematically showing an example of the configuration of an optical magnetic field probe used in the present embodiment. The optical magnetic field probe 50 has a configuration similar to the optical voltage probe 3, and comprises a loop antenna 54 instead of the contact terminals 16 and 17 of the optical voltage probe 3. When a magnetic field component in the X-axis direction passing through the loop antenna 54 changes due to the electrical shock, a voltage signal is generated by an induced electromotive force, the voltage signal is applied to the modulation electrode 14, the input light 55 is intensity-modulated, and an optical trigger signal 56 is obtained. Note that the optical magnetic field probe 50 can detect a change in the magnetic field generated by the current by arranging the loop antenna 54 in proximity to a conductor through which a current signal flows. Thus, the optical magnetic field probe 50 can also be used as an optical current probe for measuring a current signal.

When the synchronization between the trigger signal and the measurement signal is required at short time intervals, it is necessary to make the lengths of the input/output optical fibers 6 and 51 used for the transmission of the signals equal, and a certain degree of adjustment is possible by selecting the lengths of the optical fibers to be used. However, when the waveforms at shorter time intervals are required, the adjustment becomes easier by inserting the variable optical delay devices 52 and 53 as shown in the present embodiment. As the variable optical delay devices 52 and 53, commercially available devices of various methods can be used in accordance with the required delay time.

### Third Embodiment

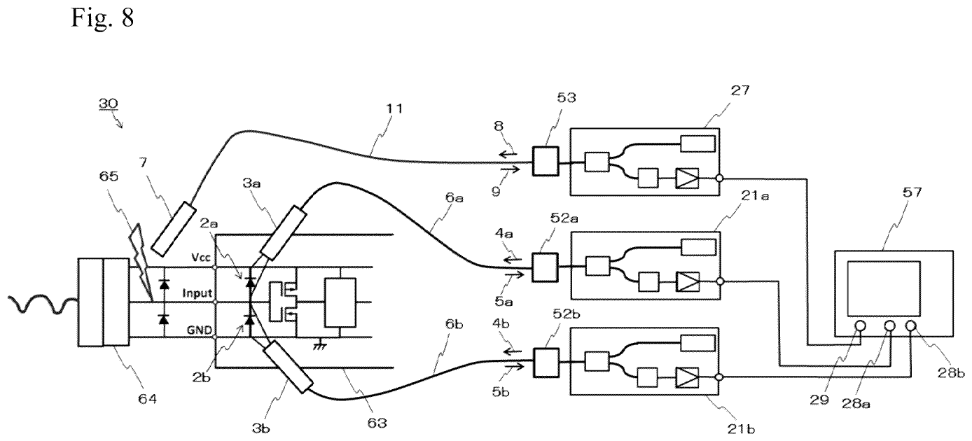

FIG. 8 is a block diagram showing the configuration of a measurement system of the third embodiment. In FIG. 8, a measurement system 30 of the present embodiment has two optical voltage probes 3a and 3b, measures the voltage signals at two measurement points 2a and 2b with the optical voltage probes, and the measurement device 57 simultaneously displays the signal waveforms of two electrical measurement signals at the measurement points 2a and 2b. In the present embodiment as well, the measurement of the electrical signal waveform is performed at the measurement points when an electrical shock is applied to an electrical component by a CDM test. However, in the present embodiment, as shown in FIG. 8, the electrical component 63 is a CMOS logic IC, and the two measurement points 2a and 2b are both ends of two diodes symmetrically arranged on the input side of the CMOS logic IC respectively. It is extremely important, for ensuring the reliability of the circuit function, to measure how each of these two voltage signals responds to the electrical shock. Note that a power supply and an input signal are input to the CMOS logic IC through a connector 64, and an electrical shock 65 of the CDM test is applied to the output side of the connector 64.

In the present embodiment, the optical voltage probes 3a and 3b used are the same as the optical voltage probe 3 of the first embodiment, and the optical trigger probe is the same as the optical electric field probe 7 of the first embodiment. An optical transmission/reception unit 21a having the same configuration as the optical transmission/reception unit 21 is used to supply an input light 4a to the optical voltage probe 3a and to convert the optical measurement signal 5a from the optical voltage probe 3a into an electrical signal. An optical transmission/reception unit 21b having the same configuration as the optical transmission/reception unit 21 is used to supply an input light 4b to the optical voltage probe 3b and to convert the optical measurement signal 5b from the optical voltage probe 3b into an electrical signal. Furthermore, the variable optical delay devices 52a and 52b are inserted between the input/output optical fibers 6a and 6b connected to the optical voltage probes 3a and 3b respectively and the optical transceiver units 21a and 21b respectively. The variable optical delay device 53 is inserted between the input/output optical fiber 11 connected to the optical electric field probe 7 and the optical transceiver unit 27.

The measurement device 57 includes two signal input terminals 28a and 28b, and the electrical measurement signal converted from the optical measurement signal 5a is input to the signal input terminal 28a, and the electrical measurement signal converted from the optical measurement signal 5b is input to the signal input terminal 28b. The electrical trigger signal converted from the optical trigger signal 9 is input to the trigger input terminal 29 of the measurement device 57, and the signal waveforms of the voltage measurement signals at the two measurement points 2a and 2b are simultaneously displayed by the trigger of the trigger signal.

It goes without saying that the present invention is not limited to the above described embodiments and the present invention can be variously modified in accordance with various purposes. For example, the optical voltage probe, the optical current probe, the optical electric field probe and the optical magnetic field probe need only be able to detect the target voltage signal, current signal, change in electric field and change in magnetic field respectively. The method and the configuration thereof can be arbitrarily selected. Furthermore, the present invention can be effectively used for measuring signal waveforms at a measurement point in various test environments where an electrical shock is applied to an electrical circuit or an electrical component in an immunity test or the like, not only ESD test.

### DESCRIPTION OF THE REFERENCE NUMERALS

1, 63: electric component; 2, 2a, 2b: measurement point; 3, 3a, 3b: optical voltage probe; 4, 4a, 4b, 8, 55: input light; 5, 5a, 5b: optical measurement signal; 6, 6a, 6b, 11, 51: input/output optical fiber; 7: optical electric field probe; 9, 56: optical trigger signal; 10, 20, 30: measurement system; 12, 13, 35a, 35b: electrode pad; 14, 35, 38: modulation electrode; 15, 36: optical modulator; 16, 17: contact terminal; 18, 19: terminal attachment portion; 21, 21a, 21b, 27: optical transmission/reception unit; 22: light source; 23, 23a: signal O/E converter; 23b: trigger O/E converter; 24: transmission/reception separator; 25: amplifier; 26: output terminal; 31, 57: measurement device; 28, 28a, 28b: signal input terminal; 29: trigger input terminal; 32, 37: package; 33: charging plate; 34: ground pin; 39a, 39b: antenna pad; 41: substrate; 42: branch interference type optical waveguide; 42a: input/output optical waveguide; 42b, 42c: phase shift optical waveguide; 43: buffer layer; 45: light reflecting portion; 46, 47, 48: electrode; 50: optical magnetic field probe; 52, 52a, 52b, 53: variable optical delay device; 54: loop antenna; 60: base; 61: ferrule; 62: fixing member; 64: connector; 65: electrical shock

1. A measurement system for measuring an electrical signal waveform at a measurement point in an electric circuit or an electric component when an electrical shock is applied to the electric circuit or the electric component, the measurement system comprising:
an optical measurement probe configured to modulate a first input light with a voltage signal or a current signal at the measurement point and output a first modulated light as an optical measurement signal through a first optical fiber;
an optical trigger probe configured to modulate a second input light by a change in an electric field or a magnetic field generated in a surrounding of the optical trigger probe due to the electrical shock and output a second modulated light as an optical trigger signal through a second optical fiber;
a light source configured to supply the first input light and the second input light to the optical measurement probe and the optical trigger probe;
a signal O/E converter configured to convert the optical measurement signal into an electrical measurement signal;
a trigger O/E converter configured to convert the optical trigger signal into an electrical trigger signal; and
a measurement device configured to receive the electrical measurement signal and the electrical trigger signal and display a signal waveform of the electrical measurement signal using the electrical trigger signal as a trigger.

2. The measurement system according to claim 1, wherein
the optical measurement probe is an optical voltage probe configured to measure the voltage signal at the measurement point, and
the optical voltage probe includes: an optical modulator configured to convert the voltage signal between two electrode pads into an optical intensity modulation signal and output the optical intensity modulation signal through the first optical fiber; two contact terminals capable of contacting the measurement point; and an electrical line connecting the two contact terminals with the two electrode pads.

3. The measurement system according to claim 1, wherein
the optical measurement probe is an optical current probe configured to measure the current signal at the measurement point, and
the optical current probe includes: an optical modulator configured to convert the voltage signal between two electrode pads into an optical intensity modulation signal and output the optical intensity modulation signal through the first optical fiber; a magnetic field antenna configured to detect a magnetic field generated by a current at the measurement point and convert the magnetic field into a voltage; and an electrical line connecting the magnetic field antenna with the two electrode pads.

4. The measurement system according to claim 1, wherein
the optical trigger probe is the optical electric field probe configured to detect the change in the electric field generated by the electrical shock,
the optical electric field probe includes an optical modulator which includes a modulation electrode and is configured to convert the voltage signal induced in the modulation electrode into an optical intensity modulation signal and output the optical intensity modulation signal through the second optical fiber, and
the voltage signal is induced in the modulation electrode by the change in the electric field or an antenna configured to induce the voltage by the change in the electric field is connected to the modulation electrode.

5. The measurement system according to claim 1, wherein
the optical trigger probe is an optical magnetic field probe configured to detect the change in the magnetic field generated by the electrical shock, and
the optical magnetic field probe includes: an optical modulator configured to convert the voltage signal between two electrode pads into an optical intensity modulation signal and output the optical intensity modulation signal through the second optical fiber; a magnetic field antenna configured to detect the change in the magnetic field and convert the change into a voltage; and an electrical line connecting the magnetic field antenna with the two electrode pads.

6. The measurement system according to claim 1, wherein
a plurality of optical measurement probes are provided, each of the plurality of optical measurement probes being the optical measurement probe, and
a plurality of electrical measurement signals obtained from the plurality of optical measurement probes is input to the measurement device and the signal waveform of the plurality of electrical measurement signals is simultaneously displayed.

7. The measurement system according to claim 1, wherein
a variable optical delay device configured to adjust a delay time of the optical measurement signal or the optical trigger signal is inserted in at least one of between the first optical fiber connected to the optical measurement probe and the signal O/E converter or between the second optical fiber connected to the optical trigger probe and the trigger O/E converter.

8. The measurement system according to claim 7, wherein
the electrical shock is applied by an Electrostatic Discharge test or a Charged Device Model test on the electrical circuit or the electrical component.
